(19) United States
(12) Patent Application Publication
(10) Pub. No.: US 2026/0211198 A1
(43) Pub. Date: Jul. 23, 2026

(54) HOUSING FOR ACCOMMODATING A PHOTONIC INTEGRATED CIRCUIT CHIP

(71) Applicant: Light Trace Photonics Ltd, Bristol (GB)

(72) Inventors: Jake Biele, Bristol (GB); Dominic Ashley Sulway, Bristol (GB)

(73) Assignee: Light Trace Photonics Ltd, Bristol (GB)

(21) Appl. No.: 19/142,411

(22) PCT Filed: Dec. 21, 2023
(86) PCT No.: PCT/GB2023/053352

§ 371 Date: Jun. 23, 2025

(30) Foreign Application Priority Data
Dec. 23, 2022 (GB) 2219747.9

(51) Int. Cl. G02B 6/42; G02B 6/44; G09B 23/22; H05K 5/00

(52) U.S. Cl. CPC G02B 6/4257; G02B 6/4273; G02B 6/4274; G02B 6/4441; G09B 23/22; H05K 5/0018

(57) ABSTRACT

There is presented a housing for accommodating a photonic integrated circuit, PIC, chip; the housing comprises a first chamber for accommodating the PIC chip. A second chamber is for accommodating electronics for operating the PIC chip. A first wall comprises a first wall portion, at least partially defining the first chamber, and comprising an optical fibre connection interface. The interface for removably connecting one or more external optical fibres to the housing and for optically linking the PIC chip to the one or more external optical fibres. A second wall portion at least partially defines the first chamber and comprises a window for observing the PIC chip from the outside of the housing. The first wall forms an external wall of the housing. A second internal wall separates, and thermally insulates, the first chamber from the second chamber.

### CROSS REFERENCE TO RELATED APPLICATION(S)

This application claims priority to International Patent Application No. PCT/GB2023/053352, filed Dec. 21, 2023, and United Kingdom Patent Application Serial No. 2219747.9, filed Dec. 23, 2022, the entire disclosures both of which are hereby incorporated by reference.

### TECHNICAL FIELD

The present disclosure relates to an integrated photonics education module.

### BACKGROUND

In integrated photonics, waveguides of high-index material are embedded in a low index material layer to guide light around a chip. By optically patterning these waveguides onto a chip, complex structures can be built which perform specialised functions on the guided light field. These structures—known as integrated photonic components—can be concatenated together to form photonic integrated circuits (PICs) which typically perform some computation or measurement of the environment. The key benefit afforded by PICs is the ability to pattern many components into a single, phase stable chip that can then be deployed much more easily than an equivalent fibre or bulk-glass setup.

Current educational devices in photonics are limited to simple bulk-glass components such as prisms, mirrors, lenses, etc. These devices are great for teaching the student about core principles of photonics such as diffraction, reflection, and magnification, however, they are much less suited to demonstrating other more complex concepts, such as waveguiding, interference and nonlinear optics, which often require the assembly of multiple components to demonstrate.

### SUMMARY

This invention leverages the key benefits of PICs to bring a suite of components to the user in a module that is designed to teach core photonic principles in a clear, fun and interactive way.

Using an integrated photonic component module to provide access to a host of basic components in a package that affords quick-and-easy, plug-and-play experimentation removes the need for difficult and lengthy alignment procedures often required with bulk or fibre-based components, allowing the user to explore these more advanced concepts over the course of a single lesson.

In this education module we may provide a photonics chip, such as a microchip, with direct access to photonic componentry (e.g., waveguides, bends, beamsplitters, phase shifters, reflectors, filters, modulators). The access may be via a grid of fibre ports that the student can connect to form a particular circuit with optical-fibre patch cords. The chip may be positioned in the module so that the user has a clear, magnified view of the chip with waveguides engineered to provide the optimal level of scattering so that the viewer may see in real time how visible laser light passes through their light circuit. By giving the user a live visual of the light traces through their circuit, we will be able to more easily teach them about key concepts such as interference. The education module typically comprises a housing for accommodating a photonic integrated circuit, PIC, chip. Thus, the module may be provided without the PIC chip and may optionally be configured to insert and possibly remove/replace the PIC chip with another PIC chip.

The educational module may have an on-board processor outputting to a screen which may be used to walk the student through basic, example experiments. The user may be able to manipulate the properties of some components by setting the voltage of metal wires that overlay them, or by applying electric fields across the components with doped materials inside the chip. In doing so, they may see first-hand how phase-differences can affect the path light takes through the chip. A back light may be provided to illuminate the chip, optionally showing labels for each component that map to the fibre port they interact with.

Integrated photonics is a growing, global market and is currently facing a shortage of integrated photonic engineers. By getting interactive, integrated photonics devices into high schools and undergraduate university labs the education module, and also its housing for accommodating the PIC, may help promote integrated photonics as a potential career path for the next generation.

There is presented, an apparatus that may be suitable for providing the user with a direct and magnified view of the photonic chip, the apparatus comprising any one or more of: a photonic integrated circuit, means for photonic chip housing, means for phase-stable operation via thermal isolation of the chip, fibre-optical components and operational electronics, means for optical magnification of the chip, and means for constant-brightness waveguide routing. Any of the above list may be used with the examples disclosed herein.

The photonic integrated circuit may comprise any one or more of: (i) means to optically couple light in to and/or out of the chip, (ii) means for performing manipulation of the light field via componentry, (iii) means to thermally or electrically tune these components separately and (iv) means to label components for enhanced education and ease of use. The photonic chip housing may comprise any one or more of, but not limited to: (i) means for environmental isolation of the chip, (ii) means for direct line of sight to the chip surface through the housing and (iii) means for backlighting the chip for a clear view. The phase-stable operation of the PIC may be at least partially accomplished via thermal isolation within the housing. The housing may optionally comprise any one or more of, but not limited to: (i) means for segmentation of the portion of the housing accommodating the PIC chip from the addressable fibre-optics, for example by comprising a plurality of chambers wherein addressable fibre optics is contained or forms part of a different chamber than the chamber accommodating the PIC chip, (ii) means for segmentation of the chip housing from operational electronics (again, for example, by locating the PIC chip in a different chamber to operational electronics) and (iii) means for segmentation of the operational electronics from the addressable fibre-optics (again, for example, by locating the addressable fibre-optics in a different chamber to operational electronics). The housing may comprise optical magnification of the chip for vertical, live viewing by a user, comprising any of, but not limited to: (i) means for optical magnification and (ii) means for direct line of sight.

The photonic integrated circuit is preferably achieved by using one singular chip with one guiding layer (for example the PIC chip being formed by using a single core material layer that is patterned to form the requisite waveguiding structures in the same plane), but could be achieved with several guiding layers or several chips of different or the same material composition. Means of electromagnetic coupling (for example optical coupling) electromagnetic radiation into and/or out of the chip is preferably achieved via edge couplers butt-coupled to a fibre array but could be achieved via other means such as photonic wire bonds, gratings, or photonic interposers. Optical fibre is preferably polarisation maintaining fibre to ensure optimal coupling in and out of the chip but can be any other type of optical fibre such as single mode, hollow core, or multimode fibre.

Means may be provided for performing manipulation of the light field via componentry include but are not limited to the patterning of buried waveguides, air-clad waveguides, rib or multilayer waveguides, metallic overlays for localised heating, or localised doping for electro-optic effects. Components may be optical components and may include but are not limited to waveguides, bends, phase shifters, beamsplitters, filters, reflectors, polarisation control, tuneable delays and interferometers. Components need not be limited to passive componentry and may include integrated modulators, detectors, lasers, or wavelength converters that require additional electronic signals, or which rely on nonlinear optics for more advanced education.

Means to thermally tune these components separately may involve setting the voltage or current through a section of metallic overlay that changes the optical characteristics of a given component. Tuning may also be achieved by changing the temperature of local regions of the chip via other methods of localised heating or via global heating of the chip. Means for electrically tuning these components separately may involve applying direct or alternating electrical field across or through the component via metallic overlays or through doped regions of the chip that change the optical characteristics.

Means to label components for enhanced education are preferably using metal or waveguide layers to pattern labels into the chip but could be post processed onto the chip or overlaid via an additional layer on the chip.

Means for environmental isolation of the chip is preferably achieved via a hermetically sealed housing but could be achieved, additionally or alternatively via resin overlay of the entire chip. Means for direct line of sight to the chip's surface through the housing is preferably achieved via a transparent (e.g. glass) or at least partially transparent window in the chip housing. Direct line of sight could also be achieved via live camera feed to a screen atop the module. Means for optical magnification of this chip is preferably achieved via a series of magnification lenses positioned above the chip. Magnification could also be achieved via live camera feed or with a series of parabolic mirrors.

Means for segmentation of the chip housing, operational electronics and addressable fibre-optics, that is beneficial for phase-stable operation, is preferably achieved by creating sealed chambers via the addition of internal walls within the module which prohibit convection between the chambers but could also be achieved by creating partial vacuum chambers between each chamber, or via active cooling of the walls of each chamber.

According to the invention, there is presented an apparatus suitable for providing the user with a light trace of substantially constant, or constant, brightness along each routing waveguide for clear and consistent highlighting of each component in use. Constant brightness may be provided by means to vary the rate of photon scattering along the length of the routing waveguide such that the total number of photons scattered per length remains constant, or substantially constant or constant within an upper and lower level of brightness. This is preferably achieved by varying the width of the waveguide along its propagation axis in a nonlinear manner such that the total number of photons scattered per length remains constant. This can also be achieved, in addition or in the alternative, by artificially increasing the sidewall roughness of the waveguide.

According to a first aspect of the present invention there is presented a housing (2) for accommodating a photonic integrated circuit, PIC, chip (4); the housing comprising: a first chamber (6) configured to accommodate the PIC chip; a second chamber (8) for accommodating electronics (10) for operating the PIC chip; a first wall comprising: a first wall portion (12), at least partially defining the first chamber, and comprising an optical fibre connection interface (14) for removably connecting one or more external optical fibres to the housing; the optical fibre connection interface for optically linking the PIC chip to the one or more external optical fibres; a second wall portion (16), at least partially defining the first chamber, and comprising a window (18) for observing the chip from the outside of the housing; wherein the first wall forms an external wall of the housing; a second wall (20) separating, and thermally insulating, the first chamber from the second chamber; the second wall being internal to the housing.

The first aspect may be adapted according to any feature or configuration described herein, including, but not limited to, any one or more of the following options.

Optionally, the housing may further comprise a further internal wall dividing the first chamber into a plurality of chambers wherein: one of the plurality of chambers accommodates the PIC chip; a further different one of the plurality of chambers accommodates at least a portion of the optical fibre connection interface.

Optionally, the second wall portion may comprise an opaque section surrounding the window wherein the opaque section prevents light entering or exiting the housing.

The housing may comprise a further wall wherein at least a portion of the further wall defines the first chamber; wherein the second wall connects the first wall to the further wall. The further wall may be a rear wall for contacting a supporting surface in use.

The housing may comprise a substantially rectangular box-like shape. The box may be substantially planar, in that the box is relatively shallow (or ‘short’ in height compared to its other perpendicular dimensions, wherein the height is the dimension extending from the third wall to the first wall).

The first wall may be substantially planar. The different wall portions of the first wall may be regions of the wall that are adjacent and connect to one another. The entire wall may be unitary in nature in that the different wall portions may be formed as one piece, optionally with other parts of the housing such as, but not limited to the second (or another) wall. The housing, or any part of it, may be formed of a heat insulating material such as a plastic. Other materials may also be used. The housing may be modular in that different parts of the housing may be manufactured or otherwise formed or created separately and then assembled together with one or more fixing means such as glue or mechanical fixing elements such as screws. The materials forming the outer walls of the housing, and optionally other walls of the housing may be opaque or substantially opaque to visible light. The window in the second wall portion may be an aperture within opaque material of the said second wall portion.

The second wall may be an elongate strip. The second wall may run from one end of the housing to another end of the housing, for example from an end adjacent to or comprising the first wall portion (of the first wall) to an opposite end adjacent to or comprising the second wall portion.

The housing may comprise a plurality of edge-walls connecting the first wall with the further (rear) wall wherein each edge wall comprises a surface bordering and facing the external environment. The edge walls may be mechanically connected together (through any means, including being unitary with each other). Different edge walls may be connected via corners. The edge walls may have planes that extend substantially perpendicular to the planes of the first and further walls. The edge walls may define a periphery of the housing that runs around, and connects to, the edge of the first wall. A first edge-wall and second edge wall may be opposite each other, with each taking a different end of the housing. The second wall may internally connect the first edge wall with the second edge wall. Third and fourth edge walls may also connect the first and second edge walls wherein the second wall is spaced from the third edge wall and the second edge wall. The second wall may run substantially parallel to the third edge wall and the fourth edge wall.

Any of the first chamber and/or second chamber may extend between the first wall and the third wall. The first chamber may extend between the second wall and the third edge-wall. The second chamber may extend between the second wall and the fourth edge-wall. Any of the first and second chamber may extend between the first and second edge walls. The edge walls and the first and further walls may form the outer walls of the housing.

The second wall may take a nonlinear (i.e., non-straight) path between the first and second edge walls. The second wall may extend proximal to, but not contact edge walls. In such examples, gaps may be used to run features such as electrical connections and/or may be filled with a resin or adhesive.

The electronics for operating the PIC chip may comprise processors or controllers that are powered by an electrical power source (such as a battery) and may output one or more electrical control signals for operating features of the PIC chip or other feature of the housing such as a light source. The housing may comprise internal quadrant regions wherein two quadrant regions are of the first chamber whilst the other two quadrant regions are of the second chamber. The quadrant regions may not be identically shaped. The quadrant region accommodating an electrical power source may be: a) adjacent the quadrant region of the second chamber accommodating the electronics for operating the PIC chip; b) adjacent the quadrant, underneath the optical fibre connection interface, in the first chamber; c) diagonally opposite the quadrant of the first chamber accommodating the PIC chip. The quadrant underneath the optical fibre connection interface may comprise optical fibres that run from that quadrant to the adjacent quadrant accommodating the PIC chip.

The housing may be configured such that the first wall comprises a third wall portion, at least partially defining the second chamber, and comprising a user input interface.

The user input device may comprise one or more buttons or control manipulandum.

The housing may be configured such that the first wall comprises: a fourth wall portion, at least partially defining the second chamber, and comprising a user display.

The user display may comprise a touch-input display.

The housing may be configured such that the second wall comprises one or more features for allowing electrical connections to pass between the first and second chambers. These features may be through-holes. The through-holes may accommodate the electrical connections and may be sealed (for example with an adhesive) to prevent fluid passing through the through hole between the first and second chambers.

The housing may optionally comprise: a first optical fibre in the first chamber; and, a second optical fibre in the first chamber; wherein: the optical fibre connection interface comprises a one or a plurality of optical fibre connection ports, each port configured to mechanically connect, and optically link, to a different external optical fibre; the first optical fibre connects to a first of the optical fibre connection ports; the second optical fibre connects to a second of the optical fibre connection ports; the first optical fibre configured in the housing to input light into a different facet of the PIC chip than the second optical fibre.

The housing may comprise a plurality of further optical fibres running internally within the housing. Any of the optical fibres may be single mode or multimode optical fibres. The optical fibres may run from the optical fibre connection interface, substantially parallel to the plane of the first wall, to the PIC chip.

The housing may further comprise one or more light sources for outputting light to be incident upon the PIC chip.

The one or more light sources may be mounted upon an inwardly facing surface of the first wall, preferably the first wall portion of the first wall. The light sources may be mounted within the first chamber.

The housing may be configured such that the one or more light sources are configured to direct light onto the PIC chip such that the said light reflects off the pick chip and directly exits the housing through the window.

The term ‘directly’ here is intended to mean that the light is incident upon the window without reflecting off another object after reflecting off the PIC chip. The one or more light sources may comprise a plurality of light sources. At least two of the plurality of light sources may direct light onto different portions of the PIC chip.

The housing may be configured such that the one or more light sources comprises a first light source having a first central wavelength and a second light source having a second central wavelength.

Any of the light sources may be controllable by the user input interface of the housing and/or a touch enabled user display of the housing. The light source may be configured to input light at an obtuse or acute angle with respect to the surface normal of the chip. Different light sources may be operative to input light at different angles to the chip than other light sources.

The materials forming the outer walls of the housing, and optionally other walls of the housing may be opaque or substantially opaque to visible light. The window in the second wall portion may be an aperture within opaque material of the said second wall portion. The window may comprise one or more layers of transparent material extending across the entirety of the aperture. The material of the window may be shaped to form one or more lenses (such as a convex lens) that provides magnifying power for a viewer to observe the chip from outside the housing. The housing may comprise a plurality of lenses in a stacked arrangement, to enable the viewer to view the chip under magnification. The stack may extend, in a stacking direction, in a direction parallel to the direction starting from the chip to the window. The lenses may be made of glass or plastic. The lens or lenses may either form the window and/or be disposed above or below the window (i.e., respectively, form part of the housing's first wall, be external to the housing or be internal to the housing).

The housing may further comprise a lens disposed about the window.

The housing may be configured such that the lens is a magnifying lens.

The housing may further comprise a battery for supplying electrical power to the electronics.

The housing may further comprise the PIC chip.

The battery may be disposed towards an opposite end of the housing to the PIC chip. The battery may be disposed in a region of the housing diagonally opposite the regions of the housing accommodating the PIC chip.

The battery may supply power to other elements of the housing or components within the housing including, but not limited to: the user display; a light inside the first chamber for illuminating the PIC chip.

According to a second aspect of the present invention there is presented an integrated optic waveguide comprising: a length along which light propagates; wherein; a first position along the length is spaced apart from a second position along the length; wherein light propagates from the first position to the second position; the integrated optic waveguide cross section changes in at least one of the following characteristics: i) waveguide width; ii) waveguide depth; iii) waveguide core refractive index; iv) waveguide core wall surface roughness; v) cross section proximity features; between the first position and second position such that light propagating between the first and second position scatters substantially the same intensity of light along the length between the first position and second position.

Cross section proximity features may be features introduced to induce scattering.

Typically, such features are disposed around the outside of the core waveguide or may be internal as well. They are typically design elements that are perturbations of the usual waveguide profile in cross section that do not substantially extend along the length of the waveguide, for example they may be sub-wavelength in dimension or possibly only extend a number of wavelengths along the length of the waveguide.

The second aspect may be adapted according to any feature or configuration described herein, including but not limited to any one or more of the following options.

The integrated optic waveguide may be configured such that the waveguide changes at least one of the characteristics i)-v) in a nonlinear manner between the first positions and the second position.

The integrated optic waveguide may be configured such that waveguide width is varied nonlinearly between the first position and second position.

The integrated optic waveguide may be configured such that the propagation loss, a (x), of the waveguide varies along the length, x, of the waveguide from the first position to the second position according to the following equation:

$$α ( x ) = \frac{1}{x} ln ( \frac{1}{1 - {α}_{c} x} )$$

wherein the starting propagation loss at the first position is a_{c}.

There is also presented a photonic light wave circuit waveguide design comprising: a first integrated optic waveguide comprising an integrated optic waveguide described above; a second integrated optic waveguide comprising an integrated optic waveguide as described above; a waveguide component connected and optically linked to the first integrated optic waveguide and the second integrated optic waveguide.

The photonic light wave circuit waveguide design may be configured such that the waveguide component comprises a first end connected to the first integrated optic waveguide; and a second end connected to the second integrated optic waveguide; such that light travels along the length of the first integrated optic waveguide, through the waveguide component and subsequently along the length of the second integrated optic waveguide.

There is also presented a device comprising a plurality of photonic light wave circuit designs described above; wherein the first and second integrated optic waveguides of each photonic light wave circuit waveguide design terminate at a separate optical input/output interface of the device.

The device may comprise: a first array of optical fibres for optically coupling to the first integrated optic waveguides of the photonic light wave circuit designs; a second array of optical fibres for optically coupling to the second integrated optic waveguides of the photonic light wave circuit designs.

According to a third aspect of the present invention there is presented a photonics integrated circuit, PIC, device comprising a plurality of integrated optic waveguide-based components distributed as an array over a region of the device wherein each of the said integrated-optic waveguide-based components is respectively connected to: an input integrated optic waveguide running from the component to a device facet; an output integrated optic waveguide running from the component to a device facet; wherein the input integrated optic waveguide is different to the output integrated optic waveguide.

The third aspect may be adapted according to any feature or configuration described herein, including but not limited to any one or more of the following options.

The photonics integrated circuit, PIC, device may be configured such that the array is a periodic distribution of components.

The photonics integrated circuit, PIC, device may be configured such that the distribution is about a plane parallel to the planer extent of the device.

The photonics integrated circuit, PIC, device may be configured such that the distribution is substantially grid-like.

The array may comprise a regular distribution, a periodic distribution of components. The PIC device may be substantially planar. The input waveguide may run to a first facet whilst the output waveguide may run to a second facet that is different to the first facet. The first and seconds facets may be at opposite ends of the device.

Any of the input waveguide or output waveguides may be those as described in the second aspect.

The integrated optic waveguide-based components may be any of, but not limited to: optical couplers or combiners, waveguide multiplexers or demultiplexers, interferometers, waveguide bends, waveguide gratings.

There is also presented a photonics teaching module comprising: the housing as described above; and any of: the device as described above; or, the photonics integrated circuit, PIC, device as described above.

According to a fourth aspect of the invention there is presented a housing (2) for accommodating a photonic integrated circuit, PIC, chip (4); the housing comprising:
a first chamber (6a) configured to accommodate the PIC chip (4); a second chamber (7);
a third chamber (8a) for accommodating electronics (10) for operating the PIC chip (4);
a first wall comprising: I) a first wall portion (12), at least partially defining the second chamber (7), and comprising an optical fibre connection interface (14) for: a) removably connecting one or more external optical fibres to the housing, and b) optically linking the PIC chip (4) to the one or more external optical fibres; II) a second wall portion (16), at least partially defining the first chamber (6a), and comprising a window (18) for observing the PIC chip (4) from the outside of the housing; wherein the first wall forms an external wall of the housing; a second wall (20) separating, and thermally insulating, the third chamber (8a) from both the second chamber (7) and first (6a) chamber; the second wall (20) being internal to the housing; a third wall (21) separating, and thermally insulating, the second chamber (7) from the first chamber (6a); the third wall being internal to the housing.

The fourth aspect may be adapted according to any feature or configuration described herein, including but not limited to any one or more of the following options, and/or any of the options presented for the first aspect.

Optionally, the second chamber is configured to accommodate at least a portion of the optical fibre connection interface (14). Optionally, the optical fibre connection interface (14) comprises at least a portion forming at least part of the first wall portion (12) of the first wall. Optionally, the optical fibre connection interface (14) comprises at least a portion extending into the second chamber (7).

Optionally, the second chamber (7) is adjacent to the first chamber (6a). Optionally, the third wall (21) comprises a through hole for accommodating one or more optical fibres extending between the first chamber 6a and the second chamber (7). Optionally, the through hole comprises a sealant sealing the through hole to prevent a fluid (such as a gas or liquid) flowing through the through hole.

According to a fifth aspect of the present invention there is presented a housing (2) for accommodating a photonic integrated circuit, PIC, chip (4); the housing comprising: a first chamber (6) configured to accommodate the PIC chip; a second chamber (8) for accommodating electronics (10) for operating the PIC chip; a first wall comprising: a first wall portion (12), at least partially defining the first chamber (6), and comprising an optical fibre connection interface (14) for removably connecting one or more external optical fibres to the housing; the optical fibre connection interface for optically linking the PIC chip to the one or more external optical fibres; a second wall portion (16), at least partially defining the first chamber, wherein the first wall forms an external wall of the housing; a second wall (20) separating, and thermally insulating, the first chamber from the second chamber; the second wall being internal to the housing.

The fifth aspect may be adapted according to any feature or configuration described herein, including but not limited to any one or more of the options presented for the first aspect.

Optionally, the housing further comprises a further internal wall dividing the first chamber into a plurality of chambers wherein: one of the plurality of chambers accommodates the PIC chip; a further different one of the plurality of chambers accommodates at least a portion of the optical fibre connection interface.

### BRIEF DESCRIPTION OF THE DRAWINGS

Preferred embodiments of the invention are now described, by way of example only, with reference to the accompanying drawings wherein:

FIG. 1 shows a schematic example of a housing for accommodating a PIC chip;

FIG. 2 shows an example of a top-down outside view of a housing;

FIG. 3 shows an example of a 3D perspective outside view of the housing of the example of FIG. 2;

FIG. 4 shows the inside of the housing of the example of FIGS. 2 and 3;

FIG. 5 shows an example of a PIC chip coupled to internal optical fibres of the housing;

FIG. 6 shows an example of a waveguide for outputting substantially constant scattered light from along its length;

FIG. 7 shows a schematic example of a housing for accommodating a PIC chip;

FIG. 8 shows a schematic example of a housing for accommodating a PIC chip with no window.

### DETAILED DESCRIPTION

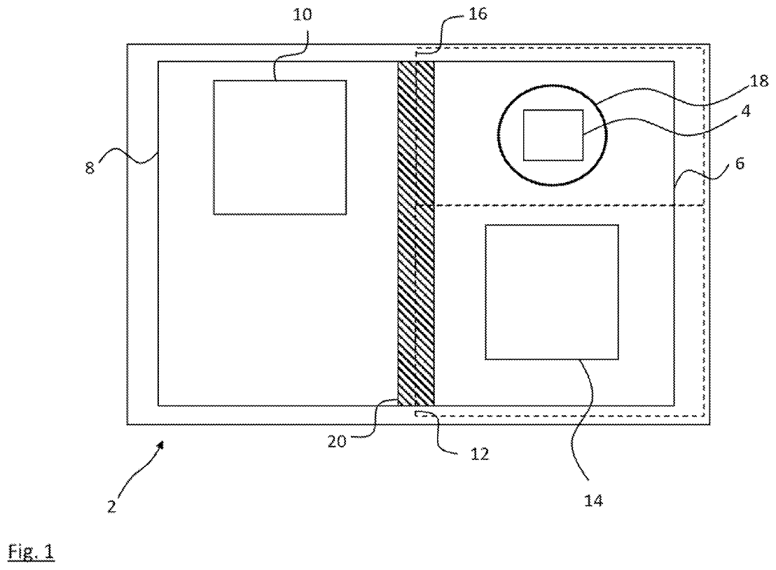

FIG. 1 shows an example of a housing 2 according to an aspect. The housing 2 is for accommodating a photonic integrated circuit, PIC, chip (4). The housing comprises a first chamber 6 configured to accommodate the PIC chip 4 The housing also comprises a second chamber 8 for accommodating electronics 10 for operating the PIC chip. The housing comprises a first wall that forms an external wall of the housing. The first wall comprises a first wall portion 12 that at least partially defines the first chamber. The first wall portion 12 comprises an optical fibre connection interface 14 for removably connecting one or more external optical fibres to the housing. The optical fibre connection interface is for optically linking the PIC chip to the one or more external optical fibres. The first wall comprises a second wall portion 16 that at least partially defines the first chamber 6. The second wall portion 16 comprises a window 18 for observing the chip from the outside of the housing 2. The housing 2 also comprises a second wall 20 separating (and thermally insulating) the first chamber from the second chamber 8. The second wall is internal to the housing 2. Preferably the window comprises a transparent material allowing light to enter or exit the chamber comprising the PIC chip. The window may be surrounded by an opaque material forming part of the wall portion comprising the window. The opaque material preventing light from entering or exiting the chamber with the PIC chip. An opaque material may be used for any internal or external wall and any portions of that wall. For example, all external walls may use an opaque material except for regions of the wall including a window. The window may therefore be a section of transparent material continuously surrounded by one or more opaque sections of the wall portion the window is accommodated in. The opaque material may form one of the one or more materials forming a substantial part of the thickness of the wall and/or may be a coating over another wall material. Any of the above options of using opaque sections of a wall, either an internal or external wall may be used with any examples herein.

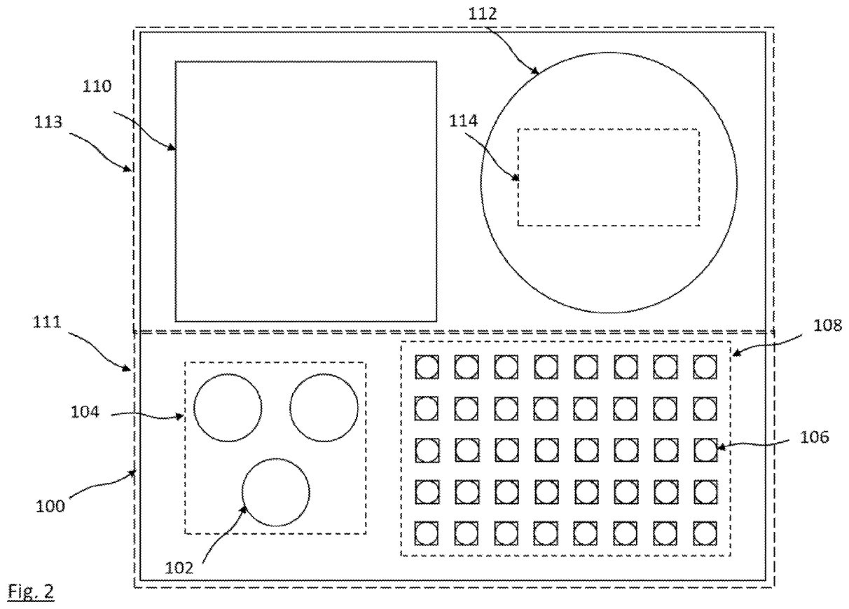

The example shown in FIG. 1 and any other example herein such as for FIGS. 2, 3, 7, and 8 may be adapted to have the optical fibre connection interface have a single connection or multiple connections. A single connection design may include a single mating port (for example female mating connections) for mechanically coupling to an optical fibre cable comprising a plurality of separate waveguiding channels. Multiple connection designs may include a plurality of such mating ports adjacent to each other in a grid or other spatial arrangement and either separated or mechanically touching each other. An example of an optical fibre cable for mating to the mating port of the interface 14 is a fibre-optic harness breakout/fanout cable, wherein the cable optionally provides a male mating end for engaging with the female mating port of the interface 14. Such a cable, or other optical fibre, may be used inside the housing for connecting the opposite side of the interface mating port to other parts of the housing, for example other chambers, in particular for guiding light to the PIC chip.

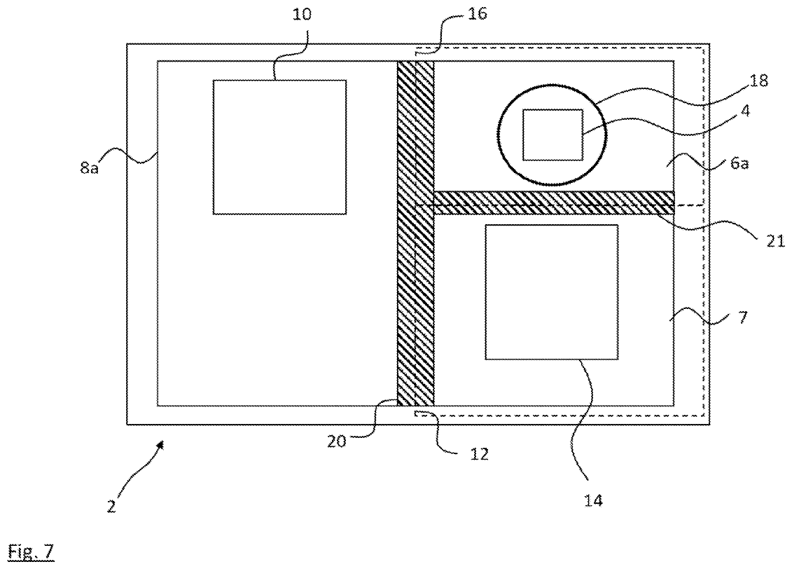

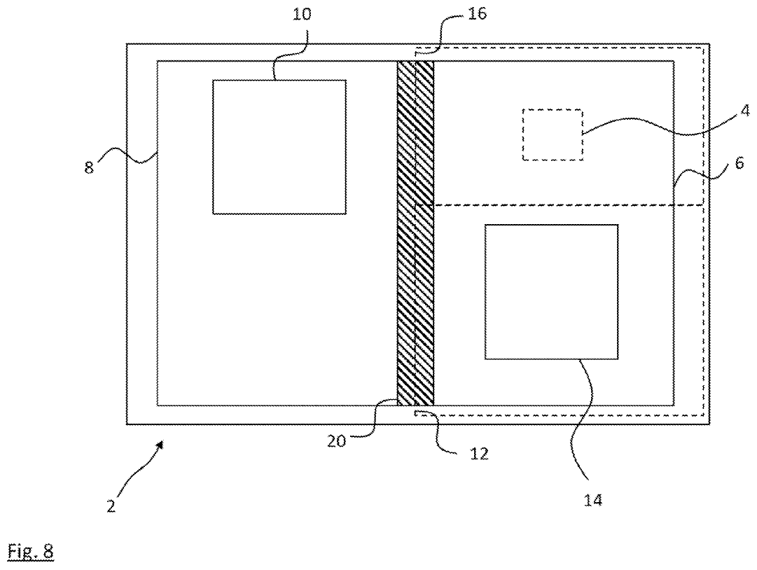

FIG. 8 shows an example of a housing similar to that shown in FIG. 1 wherein like numerals represent like components. In this figure, the first wall does not comprise a window. The example shown in FIG. 8 may include any of the configurations and adaptions of other examples herein including examples with further internal walls 21, such as in FIG. 7 or use of opaque materials for the first wall or any other external wall.

FIG. 7 shows an example of a housing similar to that shown in FIG. 1 wherein like reference numbers show like components. In the example of FIG. 7, the housing 2 comprises three chambers, but may comprise further chambers if required. The first chamber 6a is configured to accommodate the PIC chip 4 and a second chamber 7 is configured to accommodate the optical fibre connection interface 14. An internal wall 21 separates the first chamber 6a and second chamber 7. The first chamber 6a and second chamber 7 in this example, together with the dividing wall 21, may occupy a substantially similar footprint to the first chamber 6 of FIG. 1. The third chamber 8a in FIG. 7 may be similar to that of the second chamber 8 of FIG. 1. The internal wall 21 in FIG. 7 may be unitary with or otherwise mechanically connect to the wall 20 separating the third chamber 8a from the first and second chambers 6a, 7. Wall 21 extends away from the wall 20, preferably in the same plane that the wall 20 extends along the edge of the third chamber 8a. The housing may comprise a peripheral wall surrounding the group of the first, second and third chambers in FIG. 7. The peripheral wall may extend around the said chambers about a plane parallel to the plane that the wall 20 extends along the edge of the third chamber 8a. Wall 21 may extend and mechanically connect between wall 20 and the peripheral wall. The first wall may optionally mechanically connect to the peripheral wall, the wall 20 and the wall 21. The first wall may cover at least part of, preferably all of, the first chamber 6a, the second chamber 7 and the third chamber 8a and may extend about a plane parallel to the plane of the peripheral wall. The first wall may act as a first cover (or top cover) for the housing 2.

Opposite the first wall may be a further wall acting as a bottom cover for the housing 2. The further wall (not shown in FIG. 7), may cover at least part of, preferably all of, the first chamber 6a, the second chamber 7 and the third chamber 8a and may extend about a plane parallel to the plane of the peripheral wall. The group of chambers comprising at least the first chamber 6a, the second chamber 7 and the third chamber 8a may be enclosed by the peripheral wall, the first wall and the further wall. The first wall portion 12 of the first wall may incorporate the optical fibre connection interface 14 such that optical fibres may be connected to the interface from outside of the housing 2 and provide EM radiation through the optical fibres, through the interface 14 and into the housing 2. The interface 14 being connected to further EM radiation guiding components such as waveguides and/or further optical fibres that reside at least partially in the second chamber 7. The optical fibre connection interface 14 may comprise one or more ferrules for allowing the removable connection to optical fibres outside of the housing 2. The waveguiding components optically linking to the internal housing side of the interface 14 may extend into the first chamber 6a through the wall 21. One or more through holes may be used in wall 21 that link the first chamber 6a to the second chamber 7. The through holes may accommodate the waveguiding components and optionally, a sealant sealing the hole. One or more through holes may alternatively be an indented recess formed along the top of the wall 21 bordering either the first wall (acting as a top cover) or the further wall (acing as a bottom cover) opposite the first wall.

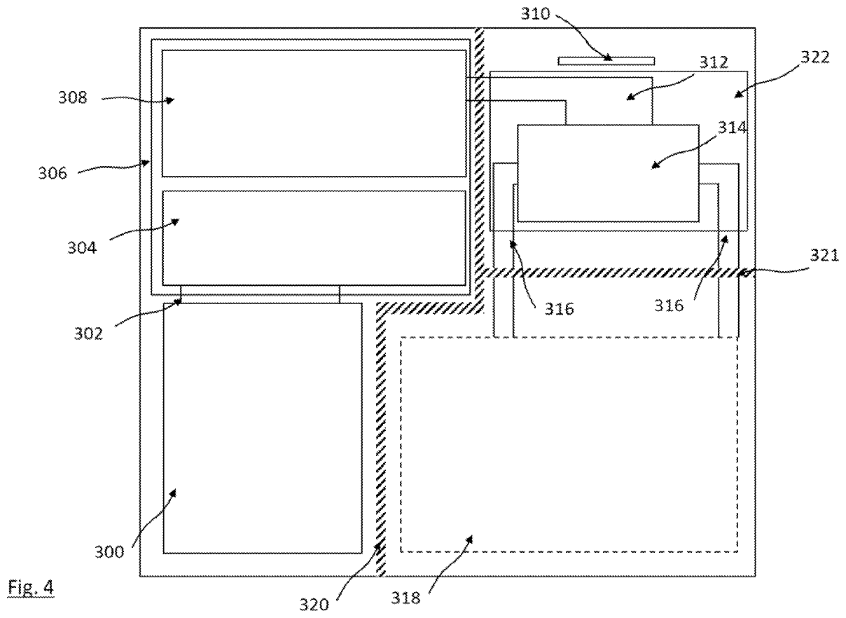

For the examples of either of FIG. 1 or 7 or 8, having insulating walls to prevent heat flow between the operational electronics, the optical fibre connection interface and the PIC chip is desirable for phase-stable operation of the entire module. FIGS. 1 and 7 and 8 show the internal wall 20 running straight along its longitudinal length across a direction running parallel to the major plane of the housing, however the wall 20 (and indeed any internal wall such as wall 21) may not necessarily run in a single straight direction but may have different straight segments joined together wherein at least one segment runs in a different direction to the other segments, such as for example insulating wall 320 of FIG. 4. It is to be understood that the features of the examples of FIG. 1 or 7 or 8 may be used in conjunction with the features describes for other examples including any of FIGS. 2, 3, 4, 5, 6.

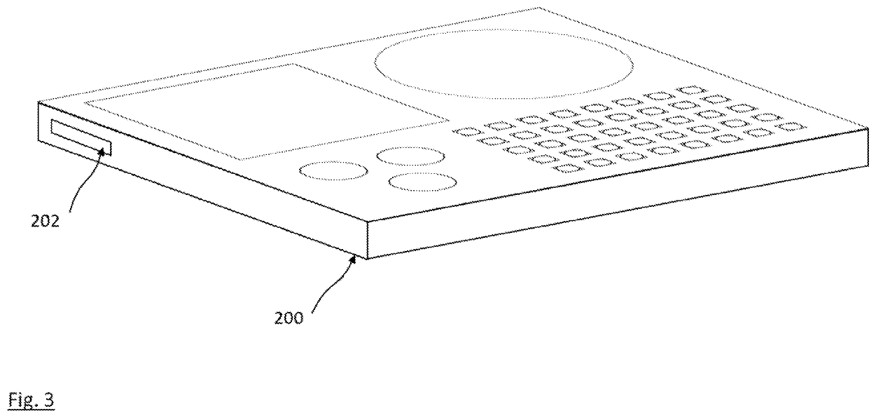

FIG. 2 shows an example of a module 100 wherein the module can be adapted to: add in further components; remove components; reconfigure components. The example of FIGS. 2 and 3 may be adapted with features according to other examples herein including those described with respect to FIGS. 1, 4, 5, 6, 7, 8. The module 100 comprises a plurality of sections about which different components are located. The sections may be defined in relation to module edges. Preferably the educational module 100 has a face for facing a user when in use. The face comprises the viewing window 112, through which the user may observe the chip within the chip housing 114. The module may have a shape in the plane of the surface that is rectangular, as exemplified in FIG. 2, however other shapes may be used such as pentagon, hexagon etc. The module may have a first end section 111 and a second end section 113 that are adjacent to each other in a plane parallel to the plane of the said user-facing face. The first end section of the module may comprise user-controllable mechanisms for controlling one or more features of the module. Mechanisms may include any of, but not limited to: fibre ferrules 106, push-button dials 102 or otherwise other user-control interfaces that allow a user to input information to the module.

In FIG. 2, the first end section 111 is shown near the bottom of the figure and comprises the ferrule grid region 108 and the group of dials 104. It should be noted that the ferrule grid 108 may be any designated area on the top surface of the module where optical fibre ferrules are located, not necessarily always in a grid. The ferrule grid (or otherwise ferrule area or region) of the user-facing surface may comprises a plurality of optical fibre connecting ports, preferably female-like connectors to receive an optical fibre connecting pigtail, such as, but not limited to a male-like FC-PC fibre end, or other male-like fibre connector end. This grid may form at least part of the interface 14 as discussed in the example of FIGS. 1 and 7. Preferably the abovesaid first end section of the module is split into two or more sub-end sections wherein each sub-end section is adjacent to the other sub-end section about a plane parallel to the plane of the user-facing face. Each sub-end section may comprise a different type of one or more components. For example, in FIG. 2 a first sub-end section is in the bottom left corner and contains the control dials 102, whilst the second sub-end section is in the bottom right corner and contains the ferrule grid 108. The first sub-end section is shown to have three dials placed in a triangular configuration, however, a singular, or multiple, dials may be used, placed in any configuration within the first sub-send section. Buttons may also be used instead of dials.

In FIG. 2 the second end section 113 is shown near the top of the figure and comprises the viewing window 112 and the display 110. Similarly, to the first end section 111, the second end section 113 may have sub-end sections wherein: a first sub-end section at the top right of the module 100 in the figure, contains the viewing window; and the second sub-end section, containing user-viewing mechanisms, is in the top left of the module 100 in the figure. The second sub-end section preferably contains a digital display window for interfacing with the user. The digital display is ideally rectangular in shape but could be another shape such as circular. The display could also be touch-screen for additional user-control of the module's mechanisms and may be multiple screens instead of one singular screen.

Having the user inputs in one section and the user viewing features in another section allows for optimised location of features such that a user can orientate the module such that the users' hands are close to the first end section, but, when operating the module, these hands are not obscuring the window 112 or display. Furthermore, having the ferrules in this first end section allows the user to group the input fibre tails (to the ferrules) and run them, as a group, away from the module. For example, the user may simply have the input fibres running directly away from the module 100 extending away from the first and second end sections in a direction substantially parallel to the plane of the module's user-facing surface. Thus, the fibres do not run over and obscure the viewing features 110, 112. If the module were to have fibre ferrules disposed around the chip viewing area 112, (possibly to coincide close to where the optical input/outputs of the chip are located), then it would be harder for the user to group these fibres without obscuring the view of the display 110 or the window 112. Additionally, if the user-interface dials were disposed around the chip or amongst the fibre grid, operation of these dials would likely disturb the fibres, introducing additional polarisation or phase drift which may affect a given experiment.

The first sub-end section of the second end section 113 at the top right is an opening that allows for magnified viewing into the chip housing 114. A magnified view of the chip allows the user to resolve individual components on the chip so that they can assess where light is passing through the chip to learn about photonics. Preferably, the opening is circular to accommodate a series of lenses, or a singular lens, stacked in a direction parallel to the chip surface to allow for magnification of the chip when viewed from above. The opening may also be other shapes such a rectangular, hexagonal, etc that allow for visual access to the chip housing below.

Preferably, lenses are stacked between the top of the chip housing and the opening. It should be noted that lenses could also be held above the top surface of the module or within the chip housing. By stacking lenses vertically above the chip housing, the user is provided with a magnified view of the entire chip, with minimal edge distortion, using a compact magnification system. If the module were to employ a set of mirrors and lenses to provide a view of the chip from another face of the module, or not directly above the chip house, the user would not be able to monitor both the chip and the user-interface from the same vantage point. By placing the magnification lenses directly above the chip, we also minimise the overall size of the magnification system to ensure the device remains as light and compact as possible for optimal classroom use. A camera may be used instead of a lens system, with the output feed passed either to an additional screen in section 112 or to the user-interface in the adjacent display 110, however, this will not provide chip viewing with the naked eye, detracting from the educational experience provided to the user by the module.

FIG. 3 shows a module 200 similar to that of FIG. 2. The module 200 has all its sections in a planar configuration for optimal bench-top use in a classroom setting. The height of the module, as depicted in FIG. 3, is preferably the smaller of the modules three dimensions, with the width and length of the module allowing for easy transportation by a singular student. It should be noted that the top-facing plane (hence the whole module 200) may be rotated along any edge of the device with additional supports to tilt the device towards the user for seated use. The module, although containing a battery, user-controls and a display window, may require a power charging port and would ideally have an additional USB port, or similar, for optional remote control via a secondary computer. These ports should ideally be placed on one side of the module, closest to the onboard processor, in a group as depicted in 202 to allow for use next to a desktop computer, however, they could be placed on any surface of the module either as a group or spread across the device.

FIG. 4 shows an example the interior of the module 100, 200 of FIGS. 2 and 3 respectively. The components and configurations shown and described with respect to FIG. 4 may be used with the examples described for FIGS. 1 and 7, 8 and vice versa. The module interior consists of a plurality of sections which are separated out according to their functions, and which align with the four main sub-end section atop the module, described above. FIG. 4 depicts these sections, showing main electrical and optical connections between the chip housing 314 and the rest of the module. The first end section of the module, underneath (in module depth dimension) the user control mechanisms and optionally the fibre grid, may comprise of a battery 300, which enables portable use in the classroom and fibre routing sections 316, from the chip housing to the fibre ferrules grid 318 for user-interfacing. The grid 318 may be part of the interface 14 described in other figures. Fibre routing sections 316 are preferably walled to form a channel in which resin or glue can be poured to set the fibres in place. This will help promote phase-stability and minimise polarisation drift as the device is moved around the classroom. This could also be achieved by using mechanical fastening such as clips or ties along the length of the fibre routing.

Preferably, the battery is located beneath the user-control interface to allow for ample space below the fibre grid for fibre connectors to bend upwards, perpendicular to the module user-facing plane. Without such space, the fibre bend radius to accommodate for this bend would be too tight, leading to high optical loss in the fibre or a taller module. Optionally the fibre inputs in the fibre grid may substantially align with an end of the chip. In other words, in FIG. 4, optical fibre inputs/outputs on the left-hand side of the photonics chip may link to fibre ferrules on the left-hand side of fibre grid area; and correspondingly, optical fibre inputs/outputs on the right-hand side of the photonics chip may link to fibre ferrules on the right-hand side of fibre grid area. This may allow for less fibre to be used internally and less crossing of fibres internally.

The second end section may have sub-end sections wherein a first sub-end section at the top right in FIG. 4 is located underneath (in module depth dimension) the chip viewing sub-section 112, and the second sub-end at the top left of FIG. 4 is located below the user display sub-section 110. This first sub-end section may comprise of the chip housing which is preferably a butterfly-type package with a clear top which may be soldered into place on a larger supporting printed circuit board 322. The chip housing preferably has optical fibre inputs and outputs on adjacent sides of the housing, with electrical pins perpendicular to these optical ports. Optical and electrical ports may not necessarily address adjacent sides of the chip housing but are preferably in plane with the supporting printed circuit. If this were not the case, ports would obstruct the users view of the chip.

Preferably, the chip housing is hermetically sealed via the use of a clear glass or plastic window material to seal the top side of the housing, whilst allowing a clear line of sight to the chip, however, the chip housing may be left unsealed with no protective top window. It should be noted that this window may be replaced by a lens which doubles as part of the magnification system. The chip may also be glued directly to a supporting printed circuit board, forgoing the need for a chip housing, or may be mounted atop a metal plate to facilitate heat transfer away from the chip, to maintain the chips temperate with respect to the surrounding environment.

Isolation of the fibre routing and fibre grid from key heat sources within the module is desirable for providing optical phase stability through the fibre and chip. To isolate the main heat-producing electronics from the optical elements, an insulating wall 320 divides the sub-end sections of both end section. In addition, to isolate the chip housing, which will also produce heat, from the optical fibre connection interface 318, a second insulating wall 321 divides the sub-end sections of both end section. The wall 321 may have similar properties and configurations as that described for wall 21 of FIG. 7. Insulation preferably runs through the entire module to minimise heat transfer. Active heat dissipation may also be used, especially around the battery, to dissipate heat to the environment. This may include a fan, directed at the battery 300, processor 304, or chip-control electronics 308. If the heat producing elements of the device were not kept adjacent, and isolated from all other elements the module would be negatively affected while the device is in operation. This would lead to unstable experimentation that may confuse the student, detracting from their learning experience. It should be noted that a stable temperature through the fibres 316 may also be achieved actively by bringing them into thermal contact with a Peltier cooler, or equivalent such technology, controlled by the processor or chip-control electronics and powered by the battery.

A backlight 310 is included to provide the user with an illuminated view of the chip within its housing. The term ‘backlight’ is used here for reference purposes only as it is understood that the light is reflected off the front of the chip. The backlight is preferably situated adjacent to the chip housing, fastened to the underside of the top user-viewing face to allow for light to reflect off the chips surface at an angle towards the user. By placing the backlight such that rays reflect off the chip at an angle, refraction of layers withing the chip may be utilised to further highlight labels that have been patterned directly onto the chip, either in the metal or guiding layer. For example, using striped font that acts as a diffraction grating at the backlight wavelength of light will highlight labels when the backlight is held at the correct angle to the face of the chip. The backlight may also be positioned within the chip housing at the correct angle to achieve the same effect. Multiple backlights may be used, positioned at different angles or along different edges of the chip housing to further highlight the device or to add multiple highlight colours, helping single out different labels for different modes of operation. In addition, a singular chromatic light source may be used, with varied diffraction grating fonts used to highlight different label in different colours.

The second sub-end section may comprise of supporting electronics, required to operate the module, and is preferably located directly under the display section, on the adjacent side of the thermal barrier to the chip housing, connected to the display and user-interface dials via cables. Operational electronics include, but are not limited to, an onboard processing unit 304, with accompanying firmware, and a chip-control module 308 to control electrical signals to the chip. Additional electronics may include a control unit for any active heat control employed within the module such as a fan or Peltier cooler. All electronics are ideally soldered to a larger motherboard 306, with connections to the chip housing through thermally isolated cables 312 to minimise heat flow from one side of the insulation to the other. The motherboard is ideally connected to the battery adjacent to it via cables 302 to minimise heat flow from the battery to the control electronics.

FIG. 4 shows the chip-control electronics adjacent to the onboard processing unit within the second sub-end section, however, the electronics within this sub-end section may not be separated out into two self-contained sections of the motherboard and may be mixed into one larger electronic system. Electronics may also be spread across more than one layer of motherboard that are stacked in a plane perpendicular to the motherboard surface within the sub-end section. Additionally, electronics may be soldered onto several smaller printed circuit boards, as opposed to one motherboard, which are connected via wires. The battery-containing sub-end section of the first section and the second sub-end section of the second section may be combined to form one larger section in which the position of all major electronic components may be soldered into a different configuration. Note that in this case, the major heat producing element, the battery, will not be as far removed from the chip as possible, leading to a greater chance of phase instability within the chip and optical fibre connection interface 14.

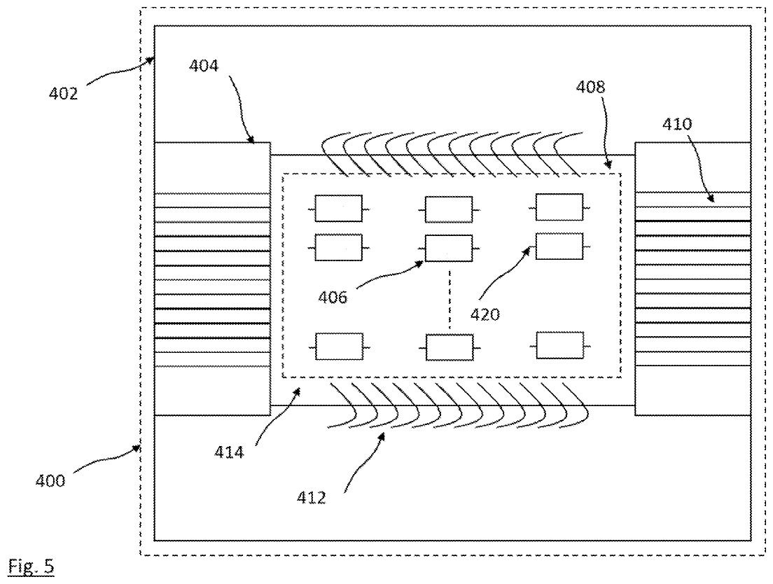

In FIG. 5, the preferred layout of components on the chip, and their electronic and optical connections within the chip housing are shown. Optical ports enter from adjacent side of the chip housing 400, preferably using a V-grooved fibre array 404 that aligns each individual fibre 410 to a coupling structure along the side of the chip. Optical ports may also enter from non-adjacent sides, or a singular side. It should be noted that other methods of optical coupling may also be used such as, but not limited to, photonic wirebonds or tapered fibres. An additional spot size converter chip may be used between the V-grooved array and the chip to optimise coupling. The V-grooved array may also have an offset angle to the side face of the chip or may couple light in from the top surface of the chip via a grating. The figure shows a V-grooved array with regular individual fibre spacing but may also have irregular spacing or singular fibres glued in place individually without a support of a V-grooved array.

The optical chip 414 is preferably a singular chip that contains a collection of components 408 including, but not limited to, variable beamsplitters, phase shifters, tuneable filters, tuneable delays, etc. Each individual component 406 is shown to be positioned in a grid to allow for quick and easy locating of specific components by the user, however, components may be positioned in any configuration within the chip, or on multiple chips that have their own optical and electronic connections. Although this layout method is not the most space efficient, without it the user will find it difficult to identify specific components, especially if they have not used a photonic integrated circuit previously and therefore do not know what each component looks like prior to use.

Electronic connections between the metal wires within the chip and the supporting printed circuit board 402 within the chip housing are ideally achieved via wirebonds 412, but could also be achieved via other means, including but not limited to, solid probes or a flip-chip bonded electronic die. FIG. 5 shows wirebonds in two sections of the chip located in rows along opposite sides of the chip to the optical ports. It should be noted that wirebonds may not necessarily be in sections of the chip and may be spread out across the chip. Having the fibre connections couple light from the chip sides, and wirebonds in sections along the chip sides, ensures the user has an unobstructed view of the components spread across the chip surface. If the wirebonds were to connect to the electrical ports of this chip from within the component grid 408, these would likely cover sections of components.

Each component has input and output waveguides that carry light from the fibres to each component 420. FIG. 5 shows each component with only one input, directing towards one fibre array, and one output directing towards the adjacent fibre array. It should be noted that each component may have several input and output waveguides connecting to one or more edges of the chip. These waveguides may also enter or leave the component from any direction and may not route to separate fibres. Routing waveguides may also have additional components in them to form a series of components or may split to route one fibre input or output to more than one component port, or to several components. Having adjacent optical ports with inputs entering one side of the chip and outputs exiting the adjacent side of the chip helps reduce the number of bends required in waveguide routing and makes for a more logical, clear configuration to help increase the users understanding of the device.

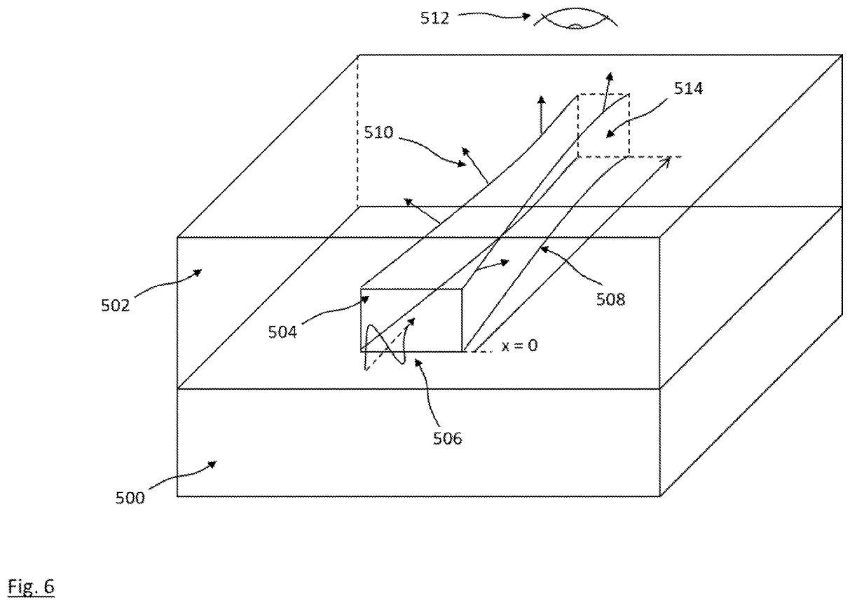

The routing waveguides are designed to scatter light (depicted in FIG. 6, 510) such that the brightness, as seen by the viewer 512, is constant along its length. Below, we present a detailed description of how to achieve constant brightness along a routing waveguide:

Prior to fabrication of the chip 414, the propagation loss of the waveguide as a function of waveguide width, α(d), is modelled. Here, d is defined as the distance from the central line of the waveguide to its sidewall i.e., half the waveguide width.

To solve for α(d) analytically, we use a model presented in Payne, F. P., Lacey, J. P. R. “A theoretical analysis of scattering loss from planar optical waveguides.” Opt. Quant. Electron 26, 977-986 (1994), which is incorporated herein by reference; which finds an analytical solution for the propagation loss of a planar waveguide under the reasonable assumption that scattering only occurs from waveguide sidewall roughness that is well described by a spectral density function, \tilde{R}(Ω), that takes the form of equation 1:

$$\tilde{R} ( Ω ) = {\int }_{- ∞}^{∞} {σ}^{2} {e}^{( - \frac{\vert u \vert}{{L}_{c}} + i Ω u )} du . \qquad [ Equ . 1 ]$$

In Equ. 1, σ is the root mean squared deviation of the waveguide sidewall from flatness and L_{c} is the characteristic correlation length of the sidewall roughness. These two parameters are typically supplied by the chip fabrication house upon request. u is the distance between any two given points along the waveguide sidewall, and its reciprocal is Ω.

By using Equ. 1, the model finds an analytical solution for α(d). We first define the following dimensionless parameters to simplify the maths in equation 2:

$$U ≡ d \sqrt{{n}_{1}^{2} {k}_{0}^{2} - {β}^{2} ,} V ≡ {k}_{0} d \sqrt{{n}_{1}^{2} - {n}_{2}^{2} ,} W ≡ d \sqrt{{β}^{2} - {n}_{2}^{2} {k}_{0}^{2} ,} s ≡ \frac{{WL}_{c}}{d} , \& γ ≡ \frac{\sqrt{2} {n}_{2} V}{W \sqrt{{n}_{1}^{2} - {n}_{2}^{2}}} \qquad [ Equ . 2 ]$$

Here, n₁ is the material index of the waveguide 504, n₂ is the material index of the cladding 502, β is the single-mode propagation constant of the waveguide, and k₀ is the free-space wavenumber. Note β is dependent on waveguide geometry and cross-section and can be calculated using any standard mode solving software (e.g., Lumerical).

α(d) can then be expressed as equation 3:

$$α ( d ) = \frac{s {σ}^{2}}{\sqrt{2} {k}_{0} {d}^{4} {n}_{1}} \frac{{U}^{2} {V}^{2}}{( 1 + W )} {( \frac{\sqrt{{( 1 + {s}^{2} )}^{2} + 2 {s}^{2} {γ}^{2}} + 1 - {s}^{2}}{{( 1 + {s}^{2} )}^{2} + 2 {s}^{2} {γ}^{2}} )}^{1 / 2} . \qquad [ Equ . 3 ]$$

Using this model, we calculate the propagation loss for any given waveguide width in which only the fundamental mode is supported.

FIG. 6 depicts an example of a routing waveguide that routes light from a fibre coupling structure 506 at the edge of the chip to a given component optical port 514.

Using the above equation, the propagation loss at the start of the routing waveguide i.e., at x=0, is calculated. We call this starting propagation loss ac.

To achieve constant brightness along the waveguide, the propagation loss is varied along the length of the waveguide such that it obeys the following equation 4 where x is propagation length along the waveguide:

$$α ( x ) = \frac{1}{x} ln ( \frac{1}{1 - {α}_{c} x} ) . \qquad [ Equ . 4 ]$$

This is preferably achieved by varying the width of the waveguide along its length as shown by 508. The required waveguide width as a function of x, can be found using Equ. 3. Specifically, the composition of the inverse of Equ. 3 applied to Equ. 4 gives the correct waveguide width as a function of propagation length. Note this can be solved numerically using these two equations.

Note also that due to the varied nonlinear nature of both α(x) and α(d), a simple linear taper in waveguide width, as typically used in integrated photonics for a variety of functions including fibre-to-chip coupling and mode mixing, cannot result in a routing waveguide of constant brightness. To highlight this, a nonlinear variation of waveguide width 508 is depicted in FIG. 6.

It should be noted that the required waveguide width as function of propagation length may be slightly different for each platform, chip fabrication method, or wavelength of operation due to the dependency of the parameters defined in Equ. 2 on the operational wavelength, material composition, sidewall roughness statistics and cross-sectional geometry.

FIG. 6 shows this methodology applied to a straight section of waveguide, however, this may also be applied to bent sections of waveguide in which the propagation loss dominates the bend loss, as is true for wide bends or Euler bends. The methodology described above is applied to a section of routing waveguide that routes light from a fibre coupling component to a component port. The scheme may also be applied in reverse, routing light from a component port to a fibre coupling component. In this case, ac is the propagation loss constant defined by the waveguide width leaving the component and x is the propagation length from the component port to the fibre coupling component.

The required affect can also be achieved by keeping the waveguide width the same along its length but adding artificial waveguide roughness to modify the propagation loss constant. This is akin to artificially increasing σ in Equ. 3. The characteristics of added noise may follow another probability distribution other than that presented in Equ. 1 across its length including, but not limited to, Gaussian noise, Rayleigh noise or white noise. Constant brightness may also be achieved via a combination of these two techniques.

The chip is shown to have a buried waveguide that sits in a low index material 502 supported by a substrate 500. The waveguide may also be exposed without cladding or suspended without full substrate support. The waveguide width at the fibre coupling component is ideally single mode at the operational wavelength but can also be multimode. As the waveguide width is decreased to induce constant brightness, the minimum width that can be achieved will be lower bounded by the single mode cut-off width of the waveguide at the operational wavelength. This places a limit on the total length of the routing waveguide which may have a constant brightness. Note this scheme may only be applied to strip waveguides due to Equ. 3 not being applicable to other types of waveguides e.g., rib-waveguides, however, the same affect could be achieved with a rib-waveguide by first measuring the form of α(d) with a series of test structures that enable estimation of propagation loss with waveguide width.

1. A housing for accommodating a photonic integrated circuit (PIC) chip, the housing comprising:
a first chamber configured to accommodate the PIC chip;
a second chamber for accommodating electronics for operating the PIC chip;
a first wall comprising:
a first wall portion, at least partially defining the first chamber, and comprising an optical fibre connection interface for removably connecting one or more external optical fibres to the housing; the optical fibre connection interface for optically linking the PIC chip to the one or more external optical fibres; and
a second wall portion, at least partially defining the first chamber, and comprising a window for observing the PIC chip from outside of the housing;
wherein the first wall forms an external wall of the housing; and
a second wall separating, and thermally insulating, the first chamber from the second chamber;
the second wall being internal to the housing.

2. The housing as claimed in claim 1 wherein the first wall comprises:
a third wall portion, at least partially defining the second chamber, and comprising a user input interface.

3. The housing as claimed in claim 1 wherein the first wall comprises:
a fourth wall portion, at least partially defining the second chamber, and comprising a user display.

4. The housing as claimed in claim 1 wherein the second wall comprises one or more features for allowing electrical connections to pass between the first and second chambers.

5. The housing as claimed in claim 1 comprising:
a first optical fibre in the first chamber, and
a second optical fibre in the first chamber;
wherein:
the optical fibre connection interface comprises a plurality of optical fibre connection ports, each port configured to mechanically connect, and optically link, to a different external optical fibre;
the first optical fibre connects to a first of the optical fibre connection ports;
the second optical fibre connects to a second of the optical fibre connection ports; and
the first optical fibre configured in the housing to input light into a different facet of the PIC chip than the second optical fibre.

6. The housing as claimed in claim 1 further comprising one or more light sources for outputting light to be incident upon the PIC chip.

7. The housing as claimed in claim 6 wherein the one or more light sources are configured to direct light onto the PIC chip such that the said light reflects off the PIC chip and directly exits the housing through the window.

8. The housing as claimed in claim 6 wherein the one or more light sources comprises a first light source having a first central wavelength and a second light source having a second central wavelength.

9. The housing as claimed in claim 1 further comprising a lens disposed about the window.

10. The housing as claimed in claim 9 wherein the lens is a magnifying lens.

11. The housing as claimed in claim 1 further comprising a battery for supplying electrical power to the electronics.

12. The housing as claimed in claim 1 further comprising the PIC chip.

13. The housing as claimed in claim 1 further comprising a further internal wall dividing the first chamber into a plurality of chambers wherein:
one of the plurality of chambers accommodates the PIC chip; and
a further different one of the plurality of chambers accommodates at least a portion of the optical fibre connection interface.

14. The housing as claimed in claim 1 wherein the second wall portion comprises an opaque section surrounding the window, the opaque section preventing light entering or exiting the housing.

15.-29. (canceled)

30. A photonics teaching module comprising:
the housing of claim 1; and
a photonics integrated circuit (PIC) device comprising a plurality of integrated optic waveguide-based components distributed as an array over a region of the PIC device, wherein each of the integrated optic waveguide-based components is respectively connected to:
an input integrated optic waveguide running from the integrated optic waveguide-based component to a device facet, and
an output integrated optic waveguide running from the integrated optic waveguide-based component to a device facet, wherein the input integrated optic waveguide is different from the output integrated optic waveguide.

31. The photonics teaching module as claimed in claim 30 wherein the array is a periodic distribution of integrated optic waveguide-based components.

32. The photonics teaching module as claimed in claim 31 wherein the periodic distribution is about a plane parallel to a planar extent of the device.

33. The photonics teaching module as claimed in claim 31 wherein the periodic distribution is substantially grid-like.

34. A housing for accommodating a photonic integrated circuit (PIC) chip, the housing comprising:
a first chamber configured to accommodate the PIC chip;
a second chamber for accommodating electronics for operating the PIC chip;
a first wall comprising:
a first wall portion, at least partially defining the first chamber, and comprising an optical fibre connection interface for removably connecting one or more external optical fibres to the housing, the optical fibre connection interface for optically linking the PIC chip to the one or more external optical fibres;
a second wall portion, at least partially defining the first chamber, wherein the first wall forms an external wall of the housing; and
a second wall separating, and thermally insulating, the first chamber from the second chamber, the second wall being internal to the housing.

35. The housing of claim 34 further comprising a further internal wall dividing the first chamber into a plurality of chambers wherein:
one of the plurality of chambers accommodates the PIC chip; and
a further different one of the plurality of chambers accommodates at least a portion of the optical fibre connection interface.
